(19) United States
(12) Patent Application Publication
(10) Pub. No.: US 2023/0203344 A1
(43) Pub. Date: Jun. 29, 2023

(54) COMPOSITION FOR CHEMICAL MECHANICAL POLISHING AND METHOD FOR POLISHING

(71) Applicant: JSR CORPORATION, Tokyo (JP)

(72) Inventors: Yuuya Yamada, Tokyo (JP); Kouhei Yoshio, Tokyo (JP)

(73) Assignee: JSR CORPORATION, Tokyo (JP)

(21) Appl. No.: 17/927,899

(22) PCT Filed: May 21, 2021
(86) PCT No.: PCT/JP2021/019426

§ 371 Date: Nov. 28, 2022

(30) Foreign Application Priority Data
Jun. 9, 2020 (JP) 2020-099777

(51) Int. Cl. C09G 1/02; H01L 21/3105; H01L 21/304

(52) U.S. Cl. CPC C09G 1/02; H01L 21/31053; H01L 21/304

(57) ABSTRACT

A composition for chemical mechanical polishing and a polishing method allow a semiconductor substrate containing at least one of a polysilicon film and a silicon nitride film to be polished at a high speed, while being capable of reducing the incidence of surface defects in the polished surface. The composition for chemical mechanical polishing contains (A) abrasive grains having plural protrusions on their surfaces and (B) a liquid medium, wherein the absolute value of the zeta-potential of the component (A) in the composition for chemical mechanical polishing is 10 mV or more.

### TECHNICAL FIELD

This invention relates to a composition for chemical mechanical polishing and a polishing method using the same.

### BACKGROUND ART

A chemical mechanical polishing (hereinafter also referred to as “CMP”) method is utilized in semiconductor manufacturing processes, particularly in flattening of interlayer insulating films, formation of metal plugs, and formation of embedded wiring (damascene wiring) in a multilayer wiring formation process. In such semiconductor manufacturing processes, materials such as polysilicon and silicon nitride are used, and not only polishing of these materials at a high speed but also polishing characteristics well-balanced between high flatness and few defects are required.

In order to realize such well-balanced polishing characteristics, for example, polishing compositions (slurry) for polishing polysilicon films and silicon nitride films have been examined (refer to Patent Literature 1 and Patent Literature 2, for example).

### CITATION LIST

### Patent Literature

Patent Literature 1: Japanese Patent Laid-Open No. 2008-235652
Patent Literature 2: Japanese Unexamined Patent Publication No. 2011-531063

### SUMMARY OF INVENTION

### Technical Problem

By using a polishing composition containing abrasive grains having high hardness, the polishing rate of polysilicon films or silicon nitride films can be improved. However, in CMP using a polishing composition containing abrasive grains having high hardness, there is a problem in that polishing scratches are likely to be generated on the polished surface. In addition, in CMP using the polishing composition containing abrasive grains having high hardness, there is a problem in that a surface defect called dishing in which a wiring material portion is shaved in a dish-like shape is likely to be generated in the surface to be polished on which a wiring material and an insulating film coexist. As described above, a composition for chemical mechanical polishing capable of reducing the incidence of surface defects in the polished surface while polishing a semiconductor substrate that contains at least one of a polysilicon film and a silicon nitride film at a high speed, and a polishing method are required.

### Solution to Problem

One aspect of a composition for chemical mechanical polishing according to this invention is a composition for chemical mechanical polishing containing:

(A) abrasive grains having a plurality of protrusions on their surfaces; and

(B) a liquid medium,

wherein the absolute value of the zeta-potential of the above component (A) in the above composition for chemical mechanical polishing is 10 mV or more.

In one aspect of the above composition for chemical mechanical polishing,

the above component (A) may have a functional group represented by general formula (1), wherein M⁺ represents a monovalent cation.

—SO₃⁻M⁺ (1)

In any of the aspects of the above composition for chemical mechanical polishing, the zeta-potential of the above component (A) in the above composition for chemical mechanical polishing may be −10 mV or lower.

In one aspect of the above composition for chemical mechanical polishing, the above component (A) may have a functional group represented by general formula (2), wherein M⁺ represents a monovalent cation.

—COO⁻M⁺ (2)

In any of the aspects of the above composition for chemical mechanical polishing, the zeta-potential of the above component (A) in the above composition for chemical mechanical polishing may be −10 mV or lower.

In one aspect of the above composition for chemical mechanical polishing, the above component (A) may have a functional group represented by general formula (3) or general formula (4).

—NR¹R² (3)

—N⁺R¹R²R³M⁻ (4)

In formulas (3) and (4) above, R¹, R², and R³ each independently represent a hydrogen atom or a substituted or unsubstituted hydrocarbon group, and M⁻ represents an anion.

In any of the aspects of the above composition for chemical mechanical polishing, the zeta-potential of the above component (A) in the above composition for chemical mechanical polishing may be +10 mV or higher.

In any of the aspects of the above composition for chemical mechanical polishing, a pH may be 1 or more and 6 or less.

In any of the aspects of the above composition for chemical mechanical polishing, the content of the above component (A) may be 0.005 mass % or more and 15 mass % or less with respect to the total mass of the above composition for chemical mechanical polishing.

In any of the aspects of the above composition for chemical mechanical polishing, the composition for chemical mechanical polishing may further contain at least one selected from the group consisting of water-soluble polymers and phosphoric acid esters.

One aspect of a polishing method according to this invention includes a step of polishing a semiconductor substrate using the composition for chemical mechanical polishing according to any of the above-mentioned aspects.

In one aspect of the above polishing method, the semiconductor substrate may have a portion containing at least one of a polysilicon film and a silicon nitride film.

### Advantageous Effects of Invention

With the composition for chemical mechanical polishing of this invention, a semiconductor substrate containing at least one of a polysilicon film and a silicon nitride film can be polished at a high speed, and the incidence of surface defects in the polished surface can be reduced. Furthermore, according to the polishing method of this invention, a surface to be polished having few surface defects can be obtained by polishing a semiconductor substrate that contains at least one of a polysilicon film and a silicon nitride film at a high speed.

### BRIEF DESCRIPTION OF DRAWINGS

FIG. 1 is a cross-sectional view schematically showing an object to be processed adapted for use in a polishing method according to this embodiment.

FIG. 2 is a cross-sectional view schematically showing the object to be processed at the completion of a first polishing step.

FIG. 3 is a cross-sectional view schematically showing the object to be processed at the completion of a second polishing step.

FIG. 4 is a perspective view schematically showing a chemical mechanical polishing apparatus.

### DESCRIPTION OF EMBODIMENTS

Hereinafter, suitable embodiments of this invention will be described in detail. This invention is not limited to the following embodiments and includes various modification examples implemented within a range not changing the gist of this invention.

In this specification, the term “wiring material” refers to conductive metal materials such as aluminum, copper, cobalt, titanium, ruthenium, and tungsten. The term “insulating film material” refers to materials such as silicon dioxide, silicon nitride, and amorphous silicon. The term “barrier metal material” refers to materials, such as tantalum nitride and titanium nitride, which are used by being laminated with wiring materials for the purpose of improving the reliability of wiring.

In this specification, the numerical value range described using “A to B” is interpreted as including the numerical value A as a lower limit value and the numerical value B as an upper limit value.

1. Composition for Chemical Mechanical Polishing

A composition for chemical mechanical polishing according to one embodiment of this invention contains: (A) abrasive grains having a plurality of protrusions on a surface (referred to as “component (A)” in this specification); and (B) a liquid medium (referred to as “component (B)” in this specification), in which the absolute value of the zeta-potential of the component (A) in the composition for chemical mechanical polishing is 10 mV or more. Hereinafter, each of the components contained in the composition for chemical mechanical polishing according to this embodiment will be described in detail.

1.1. Component (A)

The composition for chemical mechanical polishing according to this embodiment contains (A) abrasive grains having a plurality of protrusions on the surface. The component (A) is not particularly limited as long as it is an abrasive grain which has a plurality of protrusions on the surface and in which the absolute value of the zeta-potential in the composition for chemical mechanical polishing is 10 mV or more.

The abrasive grains having a plurality of protrusions on the surface can be produced by applying methods disclosed in Japanese Patent Laid-Open No. 2007-153732 and Japanese Patent Laid-Open No. 2013-121631, for example. By modifying at least a part of the surface of the abrasive grain obtained as above with a functional group, an abrasive grain which has a plurality of protrusions on the surface and in which an absolute value of a zeta-potential in the composition for chemical mechanical polishing is 10 mV or more can be produced.

The absolute value of the zeta-potential of the component (A) in the composition for chemical mechanical polishing is 10 mV or more, is preferably 15 mV or more, and is more preferably 20 mV or more. The absolute value of the zeta-potential of the component (A) in the composition for chemical mechanical polishing is preferably 40 mV or less. When the absolute value of the zeta-potential of the component (A) in the composition for chemical mechanical polishing is within the above-mentioned range, the dispersibility of the abrasive grains in the composition for chemical mechanical polishing is improved by the electrostatic repulsion between the abrasive grains. As a result, a surface to be polished can be polished at a high speed while reducing the generation of polishing scratches and dishing on the surface to be polished.

The average particle size of the component (A) is preferably 10 nm or more and 300 nm or less, and is more preferably 20 nm or more and 200 nm or less. When the average particle size of the component (A) is within the above-mentioned range, a sufficient polishing rate may be obtained, and a composition for chemical mechanical polishing having excellent stability in which sedimentation or separation of particles do not occur may also be obtained. The average particle size of the component (A) can be obtained by measuring a specific surface area by a BET method using an automatic flow-type specific surface area measurement device (manufactured by Shimadzu Corporation, “Micrometrics FlowSorb II 2300”) and calculating from this measurement value, for example.

The component (A) has a plurality of protrusions on the surface. The protrusion referred to herein has a height and a width which are sufficiently smaller than the particle size of the abrasive grains. The average number of the protrusions on the surface of the component (A) is preferably 3 or more and is more preferably 5 or more per abrasive grain. It can be said that the component (A) is an abrasive grain having a specific shape such as a so-called confetti-like shape. Since the component (A) has such a specific shape, the polishing rate of a semiconductor substrate containing at least one of a polysilicon film and a silicon nitride film is improved as compared to when spherical abrasive grains are used. In addition, since the component (A) has such a specific shape, the surface area is increased, by which the reactivity with a compound having a functional group to be described later is increased. This increases the absolute value of the zeta-potential of the component (A) in the composition for chemical mechanical polishing, thereby improving the dispersibility. As a result, a surface to be polished can be polished at a high speed while reducing the generation of polishing scratches and dishing on the surface to be polished.

The component (A) preferably contains silica as a main component. When the component (A) contains silica as a main component, other components may also be contained. Examples of the other components include aluminum compounds and silicon compounds. When the component (A) further contains an aluminum compound or a silicon compound, the surface hardness of the component (A) can be reduced, which makes it possible to further reduce the generation of polishing scratches and dishing on the surface to be polished in some cases while polishing a semiconductor substrate containing at least one of a polysilicon film and a silicon nitride film at a high speed.

Examples of the aluminum compounds include aluminum hydroxide, aluminum oxide (alumina), aluminum chloride, aluminum nitride, aluminum acetate, aluminum phosphate, aluminum sulfate, sodium aluminate, and potassium aluminate. Meanwhile, examples of the silicon compounds include silicon nitride, silicon carbide, silicates, silicones, and silicon resins.

The component (A) is preferably an abrasive grain in which at least a part of its surface has been modified with a functional group. The abrasive grain in which at least a part of the surface has been modified with a functional group has a larger absolute value of a zeta-potential than an abrasive grain in which a surface has not been modified with a functional group in a pH range of 1 or more and 6 or less, which increases the electrostatic repulsion between the abrasive grains. As a result, the dispersibility of the abrasive grains in the composition for chemical mechanical polishing is improved, which makes polishing at a high speed possible while reducing the generation of polishing scratches and dishing.

Hereinafter, specific aspects of the component (A) will be described in detail.

1.1.1. First Aspect

A first aspect of the component (A) includes abrasive grains having a functional group represented by general formula (1) and having a plurality of protrusions on the surface,

—SO₃⁻M⁺ (1)

wherein M⁺ represents a monovalent cation.

Examples of the monovalent cation represented by M⁺ in Formula (1) above include, but are not limited to, H⁺, Li⁺, Na⁺, K⁺, and NH₄⁺. That is, the functional group represented by general formula (1) above can also be rephrased as “at least one functional group selected from the group consisting of a sulfo group and a salt thereof”. The term “a salt of a sulfo group” refers to a functional group in which a hydrogen ion contained in the sulfo group (—SO₃H) has been substituted with a monovalent cation such as Li⁺, Na⁺, K⁺, and NH₄⁺. The component (A) according to the first aspect is an abrasive grain in which the functional group represented by general formula (1) above is fixed to the surface thereof via a covalent bond, and does not include an abrasive grain in which a compound having the functional group represented by general formula (1) above is physically or ionically adsorbed on the surface thereof.

The component (A) according to the first aspect can be produced as follows. First, silica having a plurality of protrusions on the surface is produced by applying methods disclosed in Japanese Patent Laid-Open No. 2007-153732 and Japanese Patent Laid-Open No. 2013-121631. Subsequently, the silica having a plurality of protrusions on the surface and a mercapto group-containing silane coupling agent are sufficiently stirred in an acidic medium to covalently bond the mercapto group-containing silane coupling agent on the surface of the silica having a plurality of protrusions on the surface. Examples of the mercapto group-containing silane coupling agent include 3-mercaptopropylmethyldimethoxysilane and 3-mercaptopropyltrimethoxysilane. Subsequently, an appropriate amount of hydrogen peroxide is further added and left to stand sufficiently, and thereby abrasive grains having the functional group represented by general formula (1) above and having a plurality of protrusions on the surface can be obtained.

The zeta-potential of the component (A) according to the first aspect is a negative potential in the composition for chemical mechanical polishing, where the negative potential is preferably −10 mV or lower, more preferably −15 mV or lower, and particularly preferably −20 mV or lower. When the zeta-potential of the component (A) according to the first aspect is within the above-mentioned range, agglomeration between particles may be effectively prevented by the electrostatic repulsion between the abrasive grains, and a positively charged substrate can also be selectively polished at the time of chemical mechanical polishing in some cases. Examples of zeta-potential measurement devices include “ELSZ-2000ZS” manufactured by Otsuka Electronics Co., Ltd., and “Zetasizer Nano Zs” manufactured by Malvern. The zeta-potential of the component (A) according to the first aspect can be adjusted by appropriately increasing or decreasing the addition amount of the above-mentioned mercapto group-containing silane coupling agent or the like.

When the composition for chemical mechanical polishing according to this embodiment contains the component (A) according to the first aspect, the content of the component (A) according to the first aspect is preferably 0.005 mass % or more, more preferably 0.1 mass % or more, and particularly preferably 0.5 mass % or more when the total mass of the composition for chemical mechanical polishing is 100 mass %. The content of the component (A) according to the first aspect is preferably 15 mass % or less, more preferably 8 mass % or less, and particularly preferably 5 mass % or less when the total mass of the composition for chemical mechanical polishing is 100 mass %. When the content of the component (A) according to the first aspect is within the above-mentioned range, a semiconductor substrate that contains at least one of a polysilicon film and a silicon nitride film can be polished at a high speed, and the preservation stability of the composition for chemical mechanical polishing becomes favorable in some cases.

1.1.2. Second Aspect

A second aspect of the component (A) includes abrasive grains having a functional group represented by general formula (2) and having a plurality of protrusions on the surface,

—COO⁻M⁺ (2)

wherein M⁺ represents a monovalent cation.

Examples of the monovalent cation represented by M⁺ in Formula (2) above include, but are not limited to, H⁺, Li⁺, Na⁺, K⁺, and NH₄⁺. That is, the functional group represented by general formula (2) above can also be rephrased as “at least one functional group selected from the group consisting of a carboxy group and a salt thereof”. The term “a salt of a carboxy group” refers to a functional group in which a hydrogen ion contained in the carboxy group (—COOH) has been substituted with a monovalent cation such as Li⁺, Na⁺, K⁺, and NH₄⁺. The component (A) according to the second aspect is an abrasive grain in which the functional group represented by general formula (2) above is fixed to the surface thereof via a covalent bond, and does not include an abrasive grain in which a compound having the functional group represented by general formula (2) above is physically or ionically adsorbed on the surface thereof.

The component (A) according to the second aspect can be produced as follows. First, silica having a plurality of protrusions on the surface is produced by applying methods disclosed in Japanese Patent Laid-Open No. 2007-153732 and Japanese Patent Laid-Open No. 2013-121631. Subsequently, silica having a plurality of protrusions on the surface and a carboxylic acid anhydride-containing silane coupling agent are sufficiently stirred in a basic medium to covalently bond the carboxylic acid anhydride-containing silane coupling agent on the surface of the abrasive grains having a plurality of protrusions on the surface, and thereby abrasive grains having the functional group represented by general formula (2) above and having a plurality of protrusions on the surface can be obtained. Examples of the carboxylic acid anhydride-containing silane coupling agent include 3-(triethoxysilyl)propylsuccinic acid anhydride.

The zeta-potential of the component (A) according to the second aspect is a negative potential in the composition for chemical mechanical polishing, where the negative potential is preferably −10 mV or lower, more preferably −15 mV or lower, and particularly preferably −20 mV or lower. When the zeta-potential of the component (A) according to the second aspect is within the above-mentioned range, agglomeration between particles is effectively prevented by the electrostatic repulsion between the abrasive grains, and a positively charged substrate can also be selectively polished at the time of chemical mechanical polishing in some cases. In addition, the device described in the first aspect can be used as a zeta-potential measurement device. The zeta-potential of the component (A) according to the second aspect can be adjusted by appropriately increasing or decreasing the addition amount of the above-mentioned carboxylic acid anhydride-containing silane coupling agent or the like.

When the composition for chemical mechanical polishing according to this embodiment contains the component (A) according to the second aspect, the content of the component (A) according to the second aspect is preferably 0.005 mass % or more, more preferably 0.1 mass % or more, and particularly preferably 0.5 mass % or more when the total mass of the composition for chemical mechanical polishing is 100 mass %. The content of the component (A) according to the second aspect is preferably 15 mass % or less, more preferably 8 mass % or less, and particularly preferably 5 mass % or less when the total mass of the composition for chemical mechanical polishing is 100 mass %. When the content of the component (A) according to the second aspect is within the above-mentioned range, a semiconductor substrate that contains at least one of a polysilicon film and a silicon nitride film can be polished at a high speed, and the preservation stability of the composition for chemical mechanical polishing becomes favorable in some cases.

1.1.3. Third Aspect

A third aspect of the component (A) includes abrasive grains having a functional group represented by general formula (3) or general formula (4) and having a plurality of protrusions on the surface.

—NR¹R² (3)

—N⁺R¹R²R³M⁻ (4)

In formula (3) above and formula (4) above, R¹, R², and R³ each independently represent a hydrogen atom or a substituted or unsubstituted hydrocarbon group, and M⁻ represents an anion.

The functional group represented by general formula (3) above represents an amino group, and the functional group represented by general formula (4) above represents a salt of the amino group. Accordingly, the functional group represented by general formula (3) above and the functional group represented by general formula (4) above can also be collectively rephrased as “at least one functional group selected from the group consisting of an amino group and a salt thereof.” The component (A) according to the third aspect is an abrasive grain in which the functional group represented by general formula (3) above or general formula (4) above is fixed to the surface thereof via a covalent bond, and does not include an abrasive grain in which a compound having the functional group represented by general formula (3) above or general formula (4) above is physically or ionically adsorbed on the surface thereof.

Examples of the anion represented by M⁻in formula (4) above include, but are not limited to, anions such as OH⁻, F⁻, Cl⁻, Br⁻, I⁻, and CN⁻, and anions derived from acidic compounds.

In formula (3) above and formula (4) above, R¹ to R³ each independently represent a hydrogen atom or a substituted or unsubstituted hydrocarbon group, but two or more of R¹ to R³ may be bonded to form a ring structure.

The hydrocarbon group represented by R¹ to R³ may be any of an aliphatic hydrocarbon group, an aromatic hydrocarbon group, an araliphatic hydrocarbon group, and an alicyclic hydrocarbon group. In addition, the aliphatic hydrocarbon group and the aliphatic moiety of the araliphatic hydrocarbon group may be saturated or unsaturated, and may be linear or branched. Examples of these hydrocarbon groups include linear, branched, and cyclic alkyl groups, alkenyl groups, aralkyl groups, and aryl groups.

As the alkyl groups, a lower alkyl group having 1 to 6 carbon atoms is generally preferable, and a lower alkyl group having 1 to 4 carbon atoms is more preferable. Examples of such alkyl groups include a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a neopentyl group, an n-hexyl group, an iso-hexyl group, a sec-hexyl group, a tert-hexyl group, a cyclopentyl group, and a cyclohexyl group.

As the alkenyl groups, a lower alkenyl group having 1 to 6 carbon atoms is generally preferable, and a lower alkenyl group having 1 to 4 carbon atoms is more preferable. Examples of such alkenyl groups include a vinyl group, an n-propenyl group, an iso-propenyl group, an n-butenyl group, an iso-butenyl group, a sec-butenyl group, and a tert-butenyl group.

As the aralkyl groups, those having 7 to 12 carbon atoms are generally preferable. Examples of such aralkyl groups include a benzyl group, a phenethyl group, a phenylpropyl group, a phenylbutyl group, a phenylhexyl group, a methylbenzyl group, a methylphenethyl group, and an ethylbenzyl group.

As the aryl groups, those having 6 to 14 carbon atoms are generally preferable. Examples of such aryl groups include a phenyl group, an o-tolyl group, an m-tolyl group, a p-tolyl group, a 2,3-xylyl group, a 2,4-xylyl group, a 2,5-xylyl group, a 2,6-xylyl group, a 3,5-xylyl group, a naphthyl group, and an anthryl group.

The aromatic rings of the above-mentioned aryl groups and aralkyl groups may have lower alkyl groups such as a methyl group and an ethyl group, a halogen atom, a nitro group, an amino group, a hydroxy group, or the like as a substituent.

The component (A) according to the third aspect can be produced as follows. First, silica having a plurality of protrusions on the surface is produced by applying methods disclosed in Japanese Patent Laid-Open No. 2007-153732 and Japanese Patent Laid-Open No. 2013-121631. Subsequently, silica having a plurality of protrusions on the surface and an amino group-containing silane coupling agent are sufficiently stirred in an acidic medium to covalently bond the amino group-containing silane coupling agent on the surface of the silica having a plurality of protrusions on the surface, and thereby abrasive grains having the functional group represented by general formula (3) above or general formula (4) above and having a plurality of protrusions on the surface is obtained. Examples of the amino group-containing silane coupling agent include 3-aminopropyltrimethoxysilane and 3-aminopropyltriethoxysilane.

The zeta-potential of the component (A) according to the third aspect is a positive potential in the composition for chemical mechanical polishing, where the positive potential is preferably +10 mV or higher, more preferably +15 mV or higher, and particularly preferably +20 mV or higher. When the zeta-potential of the component (A) according to the third aspect is within the above-mentioned range, agglomeration between particles is effectively prevented by the electrostatic repulsion between the abrasive grains, and a negatively charged substrate can also be selectively polished at the time of chemical mechanical polishing in some cases. In addition, the device described in the first aspect can be used as a zeta-potential measurement device. The zeta-potential of the component (A) according to the third aspect can be adjusted by appropriately increasing or decreasing the addition amount of the above-mentioned amino group-containing silane coupling agent or the like.

When the composition for chemical mechanical polishing according to this embodiment contains the component (A) according to the third aspect, the content of the component (A) according to the third aspect is preferably 0.005 mass % or more, more preferably 0.1 mass % or more, and particularly preferably 0.5 mass % or more when the total mass of the composition for chemical mechanical polishing is 100 mass %. The content of the component (A) according to the third aspect is preferably 15 mass % or less, more preferably 8 mass % or less, and particularly preferably 5 mass % or less when the total mass of the composition for chemical mechanical polishing is 100 mass %. When the content of the component (A) according to the third aspect is within the above-mentioned range, a semiconductor substrate that contains at least one of a polysilicon film and a silicon nitride film can be polished at a high speed, and the preservation stability of the composition for chemical mechanical polishing becomes favorable in some cases.

1.2. (B) Liquid Medium

The composition for chemical mechanical polishing according to this embodiment contains (B) a liquid medium. Examples of the component (B) include water, a mixed medium of water and alcohol, and a mixed medium containing water and an organic solvent compatible with water. Among these, it is preferable to use water or a mixed medium of water and alcohol, and it is more preferable to use water. Water is not particularly limited, but pure water is preferable. The water content is not particularly limited as long as water is blended as the remainder of the constituent materials of the composition for chemical mechanical polishing.

1.3. Other Components

In addition to each of the components described above, if necessary, the composition for chemical mechanical polishing according to this embodiment may contain organic acids and salts thereof, phosphoric acid esters, water-soluble polymers, nitrogen-containing heterocyclic compounds, surfactants, inorganic acids and salts thereof, basic compounds, or the like.

<Organic Acid and Salt Thereof>

The composition for chemical mechanical polishing according to this embodiment may contain at least one selected from the group consisting of an organic acid and a salt thereof. The organic acid and a salt thereof have a synergistic effect with the component (A), thereby exerting a function effect of increasing the polishing rate of the polysilicon film and/or the silicon nitride film.

The organic acid and a salt thereof are preferably compounds having a carboxy group and compounds having a sulfo group. Examples of the compounds having a carboxy group include stearic acid, lauric acid, oleic acid, myristic acid, alkenylsuccinic acid, lactic acid, tartaric acid, fumaric acid, glycolic acid, phthalic acid, maleic acid, formic acid, acetic acid, oxalic acid, citric acid, malic acid, malonic acid, glutaric acid, succinic acid, benzoic acid, quinolinic acid, quinaldic acid, amidosulfuric acid, propionic acid, and trifluoroacetic acid; amino acids such as glycine, alanine, aspartic acid, glutamic acid, lysine, arginine, tryptophan, aminoethyldodecylaminoethylglycine, aromatic amino acids, and heterocyclic amino acid; imino acids such as alkyliminodicarboxylic acid; and salts thereof. Examples of the compounds having a sulfo group include alkylbenzenesulfonic acids such as dodecylbenzenesulfonic acid and p-toluenesulfonic acid; alkylnaphthalenesulfonic acids such as butylnaphthalenesulfonic acid; and α-olefinsulfonic acids such as tetradecenesulfonic acid. For these compounds, one type may be used alone or two or more types may be used in combination.

When the composition for chemical mechanical polishing according to this embodiment contains an organic acid (salt), the content of the organic acid (salt) is preferably 0.001 mass % or more and is more preferably 0.01 mass % or more when the total mass of the composition for chemical mechanical polishing is 100 mass %. The content of the organic acid (salt) is preferably 5 mass % or less and is more preferably 1 mass % or less when the total mass of the composition for chemical mechanical polishing is 100 mass %.

<Phosphoric Acid Ester>

The composition for chemical mechanical polishing according to this embodiment may contain a phosphoric acid ester. A phosphoric acid ester can enhance the effect of reducing the generation of dishing by being adsorbed on the surface of a wiring material in some cases.

In general, phosphoric acid esters are a general term for compounds having a structure in which all or a part of three hydrogens of phosphoric acid (O═P(OH)₃) has been substituted with organic groups, but among phosphoric acid esters, polyoxyethylene alkyl ether phosphate esters can be preferably used from the viewpoint of a particularly favorable effect of reducing the generation of dishing. A polyoxyethylene alkyl ether phosphate ester is a nonionic type anionic surfactant and can be represented by general formula (5).

[R⁴—O—(CH₂CH₂O)ₙ]ₘ—H₃₋ₘPO₄₋ₘ (5)

In formula (5) above, R⁴ represents a hydrocarbon group having 10 or more carbon atoms, n is equal to or more than 5 and less than 30, and m is 1 or 2. The hydrocarbon group having 10 or more carbon atoms represented by R⁴ is preferably an alkyl group having 10 or more carbon atoms, and is more preferably an alkyl group having 10 to 30 carbon atoms. Specific examples of the alkyl group having 10 to 30 carbon atoms include a decyl group, an isodecyl group, a lauryl group, a tridecyl group, a cetyl group, an oleyl group, and a stearyl group. In formula (5) above, when m=2, two R⁴'s may be the same group or may be a combination of multiple groups. The molecular weight of such a polyoxyethylene alkyl ether phosphate ester is usually 400 or more.

Specific examples of polyoxyethylene alkyl ether phosphate esters include phosphoric acid monoesters of polyoxyethylene decyl ether, phosphoric acid diesters of polyoxyethylene decyl ether, phosphoric acid monoesters of polyoxyethylene isodecyl ether, phosphoric acid diesters of polyoxyethylene isodecyl ether, phosphoric acid monoesters of polyoxyethylene lauryl ether, phosphoric acid diesters of polyoxyethylene lauryl ether, phosphoric acid monoesters of polyoxyethylene tridecyl ether, phosphoric acid diesters of polyoxyethylene tridecyl ether, phosphoric acid monoesters of polyoxyethylene allyl phenyl ether, and phosphoric acid diesters of polyoxyethylene allylphenyl ether. These can be used alone or in combination of two or more types thereof. Furthermore, these polyoxyethylene alkyl ether phosphate esters include monoesters, diesters, and the like, but in this invention, monoesters and diesters each may be used alone or may be used as a mixture.

When the composition for chemical mechanical polishing according to this embodiment contains a phosphoric acid ester, the content of the phosphoric acid ester is preferably 0.001 mass % or more and is more preferably 0.002 mass % or more when the total mass of the composition for chemical mechanical polishing is 100 mass %. The content of the phosphoric acid ester is preferably 0.1 mass % or less and is more preferably 0.01 mass % or less when the total mass of the composition for chemical mechanical polishing is 100 mass %.

<Water-Soluble Polymer>

The composition for chemical mechanical polishing according to this embodiment may contain a water-soluble polymer. The water-soluble polymer is adsorbed on the surface of a surface to be polished to reduce polishing friction, and thereby the generation of dishing on the surface to be polished can be reduced in some cases.

Specific examples of the water-soluble polymer include polycarboxylic acid, polystyrenesulfonic acid, polyacrylic acid, polymethacrylic acid, polyether, polyacrylamide, polyvinyl alcohol, polyvinylpyrrolidone, polyethyleneimine, polyallylamine, and hydroxyethylcellulose. These can be used alone or in combination of two or more types thereof.

The weight-average molecular weight (Mw) of the water-soluble polymer is preferably 10,000 or more and 1,500,000 or less, and more preferably 40,000 or more and 1,200,000 or less. The term “weight-average molecular weight” refers to a weight-average molecular weight in terms of polyethylene glycol measured by gel permeation chromatography (GPC).

When the composition for chemical mechanical polishing according to this embodiment contains the water-soluble polymer, the content of the water-soluble polymer is preferably 0.001 mass % or more and is more preferably 0.002 mass % or more when the total mass of the composition for chemical mechanical polishing is 100 mass %. The content of the water-soluble polymer is preferably 0.1 mass % or less and is more preferably 0.01 mass % or less when the total mass of the composition for chemical mechanical polishing is 100 mass %.

<Nitrogen-Containing Heterocyclic Compound>

A nitrogen-containing heterocyclic compound is an organic compound containing at least one heterocyclic ring having at least one nitrogen atom and selected from five-membered heterocyclic rings and six-membered heterocyclic rings. Specific examples of the above-mentioned heterocyclic ring include five-membered heterocyclic rings such as a pyrrole structure, an imidazole structure, and a triazole structure; and six-membered heterocyclic rings such as a pyridine structure, a pyrimidine structure, a pyridazine structure, and a pyrazine structure. These heterocyclic rings may form a fused ring. Specific examples include an indole structure, an isoindole structure, a benzimidazole structure, a benzotriazole structure, a quinoline structure, an isoquinoline structure, a quinazoline structure, a cinnoline structure, a phthalazine structure, a quinoxaline structure, and an acridine structure. Among heterocyclic compounds having such structures, heterocyclic compounds having a pyridine structure, a quinoline structure, a benzimidazole structure, and a benzotriazole structure are preferable.

Specific examples of the nitrogen-containing heterocyclic compound include aziridine, pyridine, pyrimidine, pyrrolidine, piperidine, pyrazine, triazine, pyrrole, imidazole, indole, quinoline, isoquinoline, benzoisoquinoline, purine, pteridine, triazole, triazolidine, benzotriazole, carboxybenzotriazole, and derivatives having skeletons thereof. Among these, at least one selected from benzotriazole and triazole is preferable. These nitrogen-containing heterocyclic compounds may be each used alone or be used in combination of two or more.

<Surfactant>

A surfactant is not particularly limited, and anionic surfactants, cationic surfactants, nonionic surfactants, and the like can be used. Examples of anionic surfactants include sulfates such as alkyl ether sulfates and polyoxyethylene alkylphenyl ether sulfates, and fluorine-based surfactants such as perfluoroalkyl compounds. Examples of cationic surfactants include aliphatic amine salts and aliphatic ammonium salts. Examples of nonionic surfactants include nonionic surfactants having a triple bond such as acetylene glycol, acetylene glycol ethylene oxide adducts, and acetylene alcohol; and polyethylene glycol-based surfactants. For these surfactants, one type may be used alone or two or more types may be used in combination.

<Inorganic Acid and Salt Thereof>

An inorganic acid is preferably at least one selected from hydrochloric acid, nitric acid, sulfuric acid, and phosphoric acid. The inorganic acid may form a salt with a base separately added in the composition for chemical mechanical polishing.

<Basic Compound>

Examples of basic compounds include organic bases and inorganic bases. As organic bases, amines are preferable, and examples thereof include triethylamine, monoethanolamine, tetramethylammonium hydroxide, tetrabutylammonium hydroxide, benzylamine, methylamine, ethylenediamine, diglycolamine, and isopropylamine. Examples of inorganic bases include ammonia, potassium hydroxide, and sodium hydroxide. Among these basic compounds, ammonia and potassium hydroxide are preferable. For these basic compounds, one type may be used alone or two or more types may be used in combination.

1.4. pH

The pH of the composition for chemical mechanical polishing according to this embodiment is preferably 1 or more and 6 or less, more preferably 2 or more and 6 or less, and particularly preferably 2.5 or more and 5.5 or less. When the pH is within the aforementioned range, the absolute value of the zeta-potential of the component (A) in the composition for chemical mechanical polishing increases, which improves the dispersibility, thereby making high-speed polishing possible while reducing generation of polishing scratches and dishing on a semiconductor substrate containing at least one of a polysilicon film and a silicon nitride film.

If necessary, the pH of the composition for chemical mechanical polishing according to this embodiment can be adjusted by appropriately increasing or decreasing the content of the organic acid and a salt thereof, the inorganic acid and a salt thereof, and the basic compound.

In this invention, pH refers to the hydrogen ion exponent, and a value thereof is measured under the conditions of 25° C. and 1 atm using a commercially available pH meter (for example, a desktop type pH meter, manufactured by HORIBA, Ltd.).

1.5. Usage

The composition for chemical mechanical polishing according to this embodiment is suitable as a polishing material for chemical mechanical polishing of a semiconductor substrate having a plurality of types of materials constituting a semiconductor device. In addition to conductive metals such as tungsten and cobalt, the semiconductor substrate that is a polishing target may have insulating film materials such as silicon oxide films, silicon nitride films, amorphous silicon, and polysilicon, and barrier metals such as titanium, titanium nitride, and tantalum nitride.

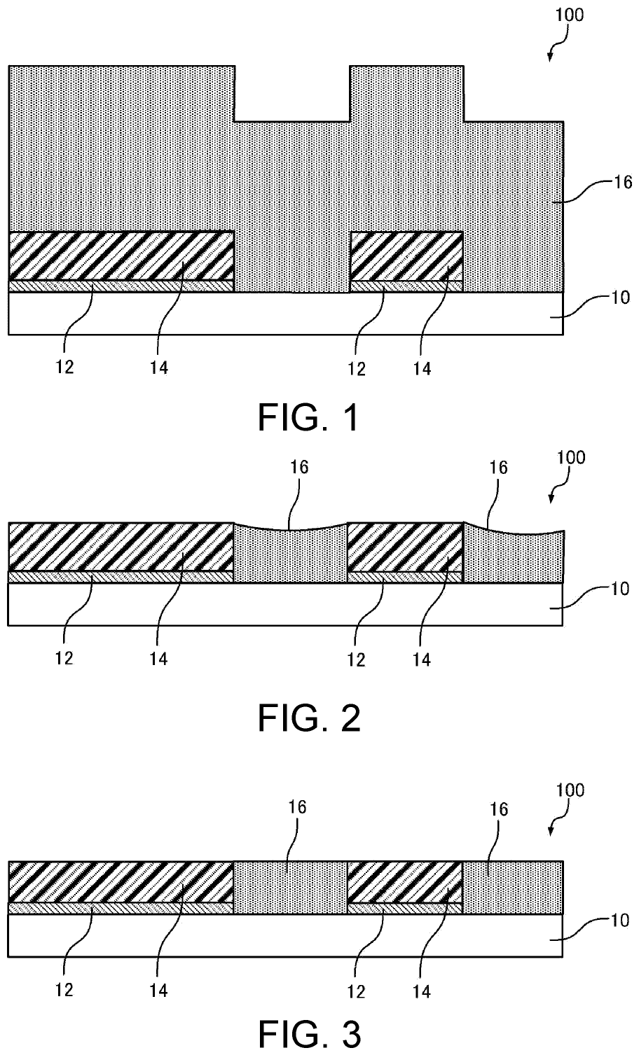

A polishing target of the composition for chemical mechanical polishing according to this embodiment is preferably a semiconductor substrate having a portion containing at least one of a polysilicon film and a silicon nitride film. Specific examples of such a semiconductor substrate include a semiconductor substrate in which a silicon nitride film has been formed onto a base material of a polysilicon film as shown in FIG. 1. According to the composition for chemical mechanical polishing according to this embodiment, such a semiconductor substrate can be polished at a high speed, and generation of surface defects on the polished surface can also be reduced.

1.6. Method for Preparing Composition for Chemical Mechanical Polishing

The composition for chemical mechanical polishing according to this embodiment can be prepared by dissolving or dispersing each of the above-mentioned components in a liquid medium such as water. A method of dissolving or dispersing is not particularly limited, and any method may be applied as long as it enables homogeneous dissolving or dispersing. In addition, a mixing order and a mixing method of each of the above-mentioned components are not particularly limited.

In addition, the composition for chemical mechanical polishing according to this embodiment can be prepared as a stock solution of a concentrated type, which is used by being diluted with a liquid medium such as water at the time of use.

2. Polishing Method

A polishing method according to one embodiment of this invention includes a step of polishing a semiconductor substrate using the above-mentioned composition for chemical mechanical polishing. The above-mentioned composition for chemical mechanical polishing can polish a semiconductor substrate having a portion containing at least one of a polysilicon film and a silicon nitride film at a high speed, and can reduce generation of surface defects on the polished surface. Accordingly, the polishing method according to this embodiment is particularly suitable when polishing a semiconductor substrate in which a silicon nitride film has been formed onto a base material of a polysilicon film. Hereinafter, a specific example of the polishing method according to this embodiment is described in detail referring to the drawings.

2.1. Object to be Processed

FIG. 1 is a cross-sectional view schematically showing an object to be processed adapted for use in the polishing method according to this embodiment. An object 100 to be processed is formed through the following steps (1) to (4).

(1) First, as shown in FIG. 1, a substrate 10 is prepared. The substrate 10 may be constituted of a silicon substrate, and a silicon oxide film formed thereon, for example. Furthermore, a functional device such as transistors (not shown) may be formed in the substrate 10. Subsequently, a silicon oxide film 12, which is an insulating film, is formed on the substrate 10 by a thermal oxidation method.

(2) Subsequently, a silicon nitride film 14 is formed on the silicon oxide film 12. The silicon nitride film 14 can be formed by, e.g., a chemical vapor deposition (CVD) method.

(3) Subsequently, a photosensitive resist film is formed on the silicon nitride film 14 by a spin coater and is selectively exposed with a photo mask to be developed. Subsequently, irradiation with plasma is performed to etch portions not having the resist. Thereafter, the protected resist is removed.

(4) Subsequently, a polysilicon film 16 of 1,500 to 2,000 Å is deposited by a chemical vapor deposition method or an electroplating method. Through the steps (1) to (4) described above, the object 100 to be processed can be produced.

2.2. Polishing Method

2.2.1. First Polishing Step

FIG. 2 is a cross-sectional view schematically showing the object 100 to be processed at the completion of a first polishing step. As shown in FIG. 2, the first polishing step is a step of roughly polishing the polysilicon film 16 using the composition for chemical mechanical polishing capable of polishing the polysilicon film 16 at a high speed. In the first polishing step, since the composition for chemical mechanical polishing capable of polishing the polysilicon film at a high speed is used, surface defects called dishing may be generated on the surface of the polysilicon film 16 as shown in FIG. 2.

2.2.2. Second Polishing Step

FIG. 3 is a cross-sectional view schematically showing the object 100 to be processed at the completion of a second polishing step. As shown in FIG. 3, the second polishing step is a step of polishing the silicon nitride film 14 and the polysilicon film 16 for flattening using the above-mentioned composition for chemical mechanical polishing (of this invention). Since the above-mentioned composition for chemical mechanical polishing (of this invention) enables controlling of the polishing rate of the polysilicon film 16 in a well-balanced manner, the generation of dishing on the polysilicon film 16 can be reduced, and the exposed silicon nitride film 14 and polysilicon film 16 can be flattened by polishing them at a high speed and in a well-balanced manner. In addition, since the dispersibility of the component (A) is favorable in the above-mentioned composition for chemical mechanical polishing (of this invention), the generation of polishing scratches on a surface to be polished can be reduced.

2.3. Chemical Mechanical Polishing Apparatus

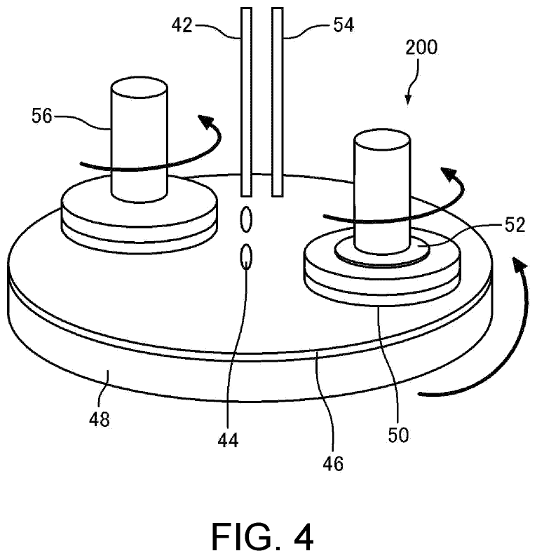

For the above-mentioned first polishing step and second polishing step, a polishing apparatus 200 as shown in FIG. 4 can be used, for example. FIG. 4 is a perspective view schematically showing a polishing apparatus 200. The above-mentioned first polishing step and the second polishing step are performed by contacting a carrier head 52 holding a semiconductor substrate 50 while supplying a slurry (composition for chemical mechanical polishing) 44 from a slurry supply nozzle 42, and rotating a turntable 48 on which a polishing cloth 46 is attached. FIG. 4 also shows a water supply nozzle 54 and a dresser 56.

The polishing load of the carrier head 52 can be selected within the range of 0.7 to 70 psi and is preferably 1.5 to 35 psi. In addition, the rotation speed of the turntable 48 and the carrier head 52 can be appropriately selected within the range of 10 to 400 rpm and is preferably 30 to 150 rpm. The flow rate of the slurry (composition for chemical mechanical polishing) 44 supplied from the slurry supply nozzle 42 can be selected within the range of 10 to 1,000 mL/minute and is preferably 50 to 400 mL/minute.

Examples of commercially available polishing apparatuses include models “EPO-112” and “EPO-222” manufactured by Ebara Corporation; models “LGP-510” and “LGP-552” manufactured by Lapmaster Sft Corporation; models “Mirra” and “Reflexion” manufactured by Applied Materials, Inc.; a model “POLI-400L” manufactured by G&P TECHNOLOGY; and a model “Reflexion LK” manufactured by AMAT.

### 3. Examples

Hereinafter, this invention will be described with reference to examples, but this invention is not limited to these examples. “Parts” and “%” in the present examples are based on mass unless explicitly described otherwise.

3.1. Preparation of Abrasive Grains

### <Preparation of Abrasive Grains A>

According to Example 6 disclosed in Japanese Patent Laid-Open No. 2007-153732, a spherical colloidal silica (abrasive grains A), which did not have a plurality of protrusions on the surface and in which the silica concentration was 12.0 mass %, the pH was 7.8, and the average particle size by dynamic light scattering was 20.1 nm, was produced.

<Preparation of Abrasive Grains B>

According to Example 7 disclosed in Japanese Patent Laid-Open No. 2007-153732, a spherical colloidal silica (abrasive grains B), which had a plurality of protrusions on the surface and in which the silica concentration was 13.7 mass %, the pH was 7.7, and the average particle size by dynamic light scattering was 45.7 nm, was produced.

<Preparation of Abrasive Grains C>

300 g of the abrasive grains B was dispersed in a mixed solvent of 100 g of pure water and 2850 g of methanol, and thereafter 50 g of 29% aqueous ammonia was added. 15.0 g of 3-mercaptopropyltrimethoxysilane was added to this dispersion liquid and refluxed at the boiling point for 6 hours. Thereafter, pure water was added to replace methanol and ammonia with water while maintaining the volume of the dispersion liquid. When the pH of the dispersion liquid reached 8.5 or less and the column top temperature reached 100° C., the addition of pure water was terminated. After the dispersion liquid was left to stand to make the temperature 30° C. or lower, 30 g of 35% hydrogen peroxide solution was added, and the dispersion liquid was further reacted for 6 hours while maintaining the temperature at about 70° C. After completion of the reaction, the dispersion liquid was left to stand to make the temperature 30° C. or lower, thereby obtaining a dispersion liquid containing abrasive grains C in which the surfaces of the abrasive grains B had been modified with sulfo groups.

<Preparation of Abrasive Grains D>

300 g of the abrasive grains B was dispersed in a mixed solvent of 100 g of pure water and 2850 g of methanol, and thereafter 50 g of 29% aqueous ammonia was added. 40.0 g of 3-(triethoxysilyl)propylsuccinic acid anhydride was added to this dispersion liquid and refluxed at the boiling point for 6 hours. Thereafter, pure water was added to replace methanol and ammonia with water while maintaining the volume of the dispersion liquid. When the pH of the dispersion liquid reached 8.5 or less and the column top temperature reached 100° C., the addition of pure water was terminated. The dispersion liquid was left to stand to make the temperature 30° C. or lower, thereby obtaining a dispersion liquid containing abrasive grains D in which the surfaces of the abrasive grains B had been modified with carboxy groups.

<Preparation of Abrasive Grains E>

1000 g of the abrasive grains B was dispersed in a mixed solvent of 100 g of pure water and 2850 g of methanol, and thereafter 5.0 g of 3-aminopropyltrimethoxysilane was added and refluxed at the boiling point for 4 hours. Thereafter, pure water was added to replace methanol with water while maintaining the volume of the dispersion liquid. The addition of pure water was terminated when the column top temperature reached 100° C., and the dispersion liquid was left to stand to make the temperature 30° C. or lower, thereby obtaining a dispersion liquid containing abrasive grains E in which the surfaces of the silica abrasive grains B had been modified with amino groups.

3.2. Preparation of Composition for Chemical Mechanical Polishing

Compositions for chemical mechanical polishing of each example and each comparative example were prepared by adding the abrasive grains shown in Tables 1 to 3 to a polyethylene bottle having the capacity of 1 L such that the concentration was a predetermined concentration, adding each component such that the composition was a composition shown in Tables 1 to 3, and furthermore, adjusting with an aqueous solution of potassium hydroxide such that the pH was a pH shown in Tables 1 to 3, and adjusting by adding pure water as (B) a liquid medium such that the total amount of all components was 100 mass %. Tables 1 to 3 collectively show the results of measuring the zeta-potential of the abrasive grains in each of the composition for chemical mechanical polishing obtained in this manner using a zeta-potential measurement device (manufactured by Otsuka Electronics Co., Ltd., model “ELSZ-2000ZS”).

3.3. Evaluation Method

### 3.3.1. Polishing Rate Evaluation

A chemical mechanical polishing test was performed for 60 seconds using the compositions for chemical mechanical polishing obtained above, and using, as an object to be processed, each of a wafer having the diameter of 12 inches and attached with a polysilicon film of 700 nm and a wafer having the diameter of 12 inches and attached with a silicon nitride film of 1000 nm under the following polishing condition.

### <Polishing Condition>

Polishing apparatus: model “POLI-400L” made by G&P TECHNOLOGY
Polishing pad: made by Fuji Boseki K.K., “multi-layer hard polyurethane pad; H800-type 1 (3-IS) 775”
Supply rate of composition for chemical mechanical polishing: 100 mL/min
Surface plate rotation speed: 100 rpm
Head rotation speed: 90 rpm
Head pressing pressure: 2 psi
Polishing rate (Å/min)=(thickness of film before polishing−thickness of film after polishing)/polishing time

The thicknesses of the polysilicon film and the silicon nitride film were calculated by measuring a refractive index using a noncontact type optical film thickness measurement device (model “NANOSPEC 6100”, manufactured by Nanometrics Japan Ltd.).

The evaluation criteria for the polishing rate are as follows. Tables 1 to 3 collectively show the polishing rates of the polysilicon film and the silicon nitride film and the evaluation results thereof.

(Evaluation criteria)
“A”: when the polishing rate of either the polysilicon film or the silicon nitride film was 300 Å/min or more, this was determined to be favorable because the polishing time of a wiring having the polysilicon film or the silicon nitride film was significantly shortened in the actual semiconductor polishing.
“B”: when the polishing rate of both the polysilicon film and the silicon nitride film was less than 300 Å/min, this was determined to be poor because the polishing rate was low, making practical use difficult.

3.3.2. Flatness Evaluation

A 12-inch wafer as an object to be processed in which a silicon nitride film of 70 nm was formed on the upper part of a silicon oxide film of 10 nm was processed into a pattern having lines and spaces of 70 nm deep and 10 μm wide and used as a test substrate on which a polysilicon film of 150 nm was laminated. This test substrate was polished until the silicon nitride film was exposed under the following condition. For the polished surface, the amount of dishing of the polysilicon/silicon nitride film wiring in the pattern portion in which the polysilicon wiring width (line, L)/silicon nitride film wiring width (space, S) were respectively 10 μm/10 μm was confirmed using a stylus profiling system (manufactured by BRUKER, model “Dektak XTL”).

### <Polishing Condition>

Polishing apparatus: model “POLI-400L” made by G&P TECHNOLOGY
Polishing pad: made by Fuji Boseki K.K., “multi-layer hard polyurethane pad; H800-type 1 (3-IS) 775”
Supply rate of composition for chemical mechanical polishing: 100 mL/min
Surface plate rotation speed: 100 rpm
Head rotation speed: 90 rpm
Head pressing pressure: 2 psi

The evaluation criteria for flatness evaluation are as follows. Tables 1 to 3 collectively show amounts of dishing and the evaluation results thereof.

### (Evaluation Criteria)

“A”: as the dishing amount was less than 5 nm, the flatness was judged to be very favorable.
“B”: as the dishing amount was 5 nm or more, the flatness was judged to be poor.

3.4. Evaluation Results

Tables 1 to 3 show the compositions and each evaluation result of the compositions for chemical mechanical polishing of each example and each comparative example.

TABLE 1

| | | | Example 1 | Example 2 | Example 3 | Example 4 | Example 5 | Example 6 | Example 7 | Example 8 |
|---|---|---|---|---|---|---|---|---|---|---|
| Composition | Abrasive | Type | Abrasive | Abrasive | Abrasive | Abrasive | Abrasive | Abrasive | Abrasive | Abrasive |
| for chemical | grain | | grain C | grain D | grain E | grain C | grain C | grain C | grain C | grain D |
| mechanical | | Zeta-potential | −34 | −10 | 35 | −24 | −15 | −30 | −34 | −23 |
| polishing | | (mV) | | | | | | | | |
| | | Zeta-potential | 34 | 10 | 35 | 24 | 15 | 30 | 34 | 23 |
| | | absolute value | | | | | | | | |
| | | Content (mass %) | 2.0 | 1.5 | 3.0 | 1.0 | 2.0 | 1.0 | 2.0 | 2.5 |
| | Other | Type | Maleic | Phosphoric | Citric | Maleic | Maleic | Phosphoric | Sulfuric | Acetic |
| | additives | | acid | acid | acid | acid | acid | acid | acid | acid |
| | | Content (mass %) | 0.06 | 0.2 | 0.2 | 0.3 | 0.6 | 0.2 | 0.01 | 0.02 |
| | pH | | 2.5 | 2.1 | 3.0 | 2.5 | 2.5 | 2.1 | 3.2 | 4.5 |
| Evaluation | Polishing | Polishing rate of | 321 | 347 | 452 | 309 | 302 | 357 | 355 | 302 |
| item | rate | polysilicon film | | | | | | | | |
| | | (Å/min) | | | | | | | | |
| | | Polishing rate of | 432 | 310 | 47 | 389 | 336 | 478 | 399 | 123 |
| | | silicon nitride | | | | | | | | |
| | | film (Å/min) | | | | | | | | |
| | | Evaluation | A | A | A | A | A | A | A | A |
| | Flatness | Amount of | 2.1 | 2.3 | 3.4 | 2.5 | 3.4 | 2.7 | 2.6 | 3.2 |
| | evaluation | dishing (nm) | | | | | | | | |
| | | Evaluation | A | A | A | A | A | A | A | A |

TABLE 2

| | | | Example 9 | Example 10 | Example 11 | Example 12 | Example 13 |
|---|---|---|---|---|---|---|---|
| Composition | Abrasive | Type | Abrasive | Abrasive | Abrasive | Abrasive | Abrasive |
| for chemical | grain | | grain E | grain C | grain C | grain C | grain C |
| mechanical | | Zeta-potential | 28 | −30 | −32 | −35 | −25 |
| polishing | | (mV) | | | | | |
| | | Zeta-potential | 28 | 30 | 32 | 35 | 25 |
| | | absolute value | | | | | |
| | | Content (mass %) | 3.0 | 2.0 | 2.0 | 2.0 | 2.0 |
| | Other | Type | Acetic | Maleic | Maleic | Maleic | Maleic |
| | additives | | acid | acid | acid | acid | acid |
| | | Content (mass %) | 0.02 | 0.06 | 0.06 | 0.05 | 0.08 |
| | | Type | | Polyvinyl | Polyethylene | Polyacrylic | Tetrabutyl- |
| | | | | alcohol | glycol | acid | ammonium |
| | | | | | | | hydroxide |
| | | Content (mass %) | | 0.01 | 0.005 | 0.005 | 0.005 |
| | pH | | 4.0 | 2.5 | 2.5 | 2.5 | 2.5 |
| Evaluation | Polishing | Polishing rate of | 317 | 441 | 302 | 421 | 454 |
| item | rate | polysilicon film | | | | | |
| | | (Å/min) | | | | | |
| | | Polishing rate of | 23 | 419 | 377 | 376 | 310 |
| | | silicon nitride | | | | | |
| | | film (Å/min) | | | | | |
| | | Evaluation | A | A | A | A | A |
| | Flatness | Amount of | 4.1 | 2.0 | 3.2 | 1.9 | 3.5 |
| | evaluation | dishing (nm) | | | | | |
| | | Evaluation | A | A | A | A | A |

| | | | Example 14 | Example 15 | Example 16 |
|---|---|---|---|---|---|
| Composition | Abrasive | Type | Abrasive | Abrasive | Abrasive |
| for chemical | grain | | grain C | grain C | grain C |
| mechanical | | Zeta-potential | −35 | −34 | −34 |
| polishing | | (mV) | | | |
| | | Zeta-potential | 35 | 34 | 34 |
| | | absolute value | | | |
| | | Content (mass %) | 2.0 | 2.0 | 2.0 |
| | Other | Type | Maleic | Maleic | Maleic |
| | additives | | acid | acid | acid |
| | | Content (mass %) | 0.05 | 0.05 | 0.05 |
| | | Type | Sodium | Dipolyoxyethylene | Polyoxyethylene |
| | | | polystyrene | alkyl ether | allylphenyl |
| | | | sulfonate | phosphate | phosphate amine |
| | | | | | salt |
| | | Content (mass %) | 0.005 | 0.004 | 0.004 |
| | pH | | 2.5 | 2.5 | 2.5 |
| Evaluation | Polishing | Polishing rate of | 341 | 302 | 348 |
| item | rate | polysilicon film | | | |
| | | (Å/min) | | | |
| | | Polishing rate of | 256 | 303 | 324 |
| | | silicon nitride | | | |
| | | film (Å/min) | | | |
| | | Evaluation | A | A | A |
| | Flatness | Amount of | 1.2 | 2.1 | 1.8 |
| | evaluation | dishing (nm) | | | |
| | | Evaluation | A | A | A |

TABLE 3

| | | | Compar- | Compar- | Compar- | Compar- | Compar- | Compar- | Compar- |
|---|---|---|---|---|---|---|---|---|---|
| | | | ative | ative | ative | ative | ative | ative | ative |
| | | | Example 1 | Example 2 | Example 3 | Example 4 | Example 5 | Example 6 | Example 7 |
| Composition | Abrasive | Type | Abrasive | Abrasive | Abrasive | Abrasive | Abrasive | Abrasive | Abrasive |
| for chemical | grain | | grain B | grain B | grain B | grain C | grain D | grain E | grain A |
| mechanical | | Zeta-potential | 5 | 4 | 4 | −9 | −3 | 7 | 3 |
| polishing | | (mV) | | | | | | | |
| | | Zeta-potential | 5 | 4 | 4 | 9 | 3 | 7 | 3 |
| | | absolute value | | | | | | | |
| | | Content (mass %) | 2.0 | 2.0 | 2.0 | 2.0 | 2.0 | 3.0 | 2.0 |
| | Other | Type | Maleic | Phosphoric | Malonic | Maleic | Phosphoric | Maleic | Maleic |
| | additives | | acid | acid | acid | acid | acid | acid | acid |
| | | Content (mass %) | 0.06 | 0.2 | 0.1 | 0.7 | 0.5 | 1.2 | 0.06 |
| | | Type | | | | Tetrabutyl- | | Sodium | |
| | | | | | | ammonium | | polystyrene | |
| | | | | | | hydroxide | | sulfonate | |
| | | Content (mass %) | | | | 0.01 | | 0.005 | |
| | pH | | 2.5 | 2.5 | 3.2 | 2.1 | 2.1 | 3.0 | 2.5 |
| Evaluation | Polishing | Polishing rate of | 321 | 345 | 338 | 211 | 321 | 142 | 172 |
| item | rate | polysilicon film | | | | | | | |
| | | (Å/min) | | | | | | | |
| | | Polishing rate of | 57 | 24 | 43 | 158 | 101 | 43 | 75 |
| | | silicon nitride | | | | | | | |
| | | film (Å/min) | | | | | | | |
| | | Evaluation | A | A | A | B | A | B | B |
| | Flatness | Amount of | 7.2 | 7.1 | 7.5 | 9.2 | 5.3 | 10.2 | 3.1 |
| | evaluation | dishing (nm) | | | | | | | |
| | | Evaluation | B | B | B | B | B | B | A |

For each of the components in Tables 1 to 3, the following products or reagents were respectively used.

### <Abrasive Grains>

Abrasive grains A: spherical colloidal silica prepared above, average particle size 20.1 nm
Abrasive grains B: colloidal silica prepared above having a plurality of protrusions on the surface, average particle size 45.7 nm
Abrasive grains C: colloidal silica in which the surfaces of the abrasive grains B had been modified with sulfo groups
Abrasive grains D: colloidal silica in which the surfaces of the abrasive grains B had been modified with carboxy groups
Abrasive grains E: colloidal silica in which the surfaces of the abrasive grains B had been modified with amino groups

### <Other Additives>

### (Organic Acid)

Maleic acid: manufactured by FUJIFILM Wako Pure Chemical Corporation, trade name “Maleic Acid”
Citric acid: manufactured by Fuso Chemical Co., Ltd., trade name “Purified Citric Acid (Crystal) L”
Acetic acid: manufactured by FUJIFILM Wako Pure Chemical Corporation, trade name “Acetic Acid”
Malonic acid: manufactured by Tokyo Chemical Industry Co., Ltd., trade name “Malonic Acid”

### (Inorganic Acid)

Phosphoric acid: manufactured by FUJIFILM Wako Pure Chemical Corporation, trade name “Phosphoric Acid”
Sulfuric acid: manufactured by FUJIFILM Wako Pure Chemical Corporation, trade name “Sulfuric Acid” (10% aqueous solution)

### (Basic Compound)

Tetrabutylammonium hydroxide: manufactured by Tokyo Chemical Industry Co., Ltd., trade name “Tetrabutylammonium Hydroxide (40% in Water)” (Water-soluble polymer)
Polyvinyl alcohol: made by JAPAN VAM & POVAL CO., LTD., trade name “PXP-05”
Polyethylene glycol: made by TOHO Chemical Industry Co., Ltd., trade name “PEG-400”
Polyacrylic acid: made by TOAGOSEI CO., LTD., trade name “JURYMERAC-10L”
Sodium polystyrene sulfonate: made by Sigma-Aldrich, trade name “Poly(sodium 4-styrenesulfonate) solution”, Mw=70,000 (Phosphoric acid ester)
Dipolyoxyethylene alkyl ether phosphate: made by Nikko Chemicals Co., Ltd., trade name “DDP-10”
Polyoxyethylene allylphenyl phosphate amine salt: made by TAKEMOTO OIL & FAT Co., Ltd., trade name “NEW CALGEN FS-3AQ” (20% aqueous solution)

According to Examples 1 to 16, it was found that by using the abrasive grains which had a plurality of protrusions on the surface and in which the absolute value of the zeta-potential in the composition for chemical mechanical polishing was 10 mV or more, the polysilicon film and/or the silicon nitride film can be polished at a high speed, and surface defects (amount of dishing) on the surface to be polished can be reduced.

Comparative Examples 1 to 6 are examples using abrasive grains which had a plurality of protrusions on the surface but had the absolute value of the zeta-potential in the composition for chemical mechanical polishing of less than 10 mV. In this case, polishing at a high speed and reduction of surface defects could not be achieved in a well-balanced manner.

Comparative Example 7 is an example using abrasive grains not having a plurality of protrusions on the surface. In this case, neither the polysilicon film nor the silicon nitride film could be polished at a high speed.

From the above results, it was found that according to the composition for chemical mechanical polishing of this invention, a semiconductor substrate that contains at least one of a polysilicon film and a silicon nitride film can be polished at a high speed, and surface defects (amount of dishing) in a surface to be polished can be reduced.

This invention is not limited to the embodiments described above, and various modifications can be made. For example, this invention includes a configuration substantially the same as the configuration described in the embodiments (for example, a configuration having the same function, method, and results, or a configuration having the same objective and effect). This invention further includes a configuration in which a non-essential part of the configuration described in the embodiments is replaced. This invention still further includes a configuration that exhibits the same function effect as the configuration described in the embodiments or a configuration that can achieve the same objective. This invention still further includes a configuration in which a known technique is added to the configuration described in the embodiments.

### REFERENCE SIGNS LIST

10: substrate
12: silicon oxide film
14: silicon nitride film
16: polysilicon film
42: slurry supply nozzle
44: composition for chemical mechanical polishing (slurry)
46: polishing cloth
48: turntable
50: semiconductor substrate
52: carrier head
54: water supply nozzle
56: dresser
100: object to be processed
200: chemical mechanical polishing apparatus

1. A composition for chemical mechanical polishing comprising:
(A) abrasive grains having a plurality of protrusions on their surfaces; and
(B) a liquid medium,
wherein an absolute value of a zeta-potential of the component (A) in the composition for chemical mechanical polishing is 10 mV or more.

2. The composition for chemical mechanical polishing according to claim 1, wherein the component (A) has a functional group represented by general formula (1),
—SO₃⁻M⁺ (1)
wherein M⁺ represents a monovalent cation.

3. The composition for chemical mechanical polishing according to claim 2, wherein the zeta-potential of the component (A) in the composition for chemical mechanical polishing is −10 mV or lower.

4. The composition for chemical mechanical polishing according to claim 1, wherein the component (A) has a functional group represented by general formula (2),
—COO⁻M⁺ (2)
wherein M⁺ represents a monovalent cation.

5. The composition for chemical mechanical polishing according to claim 4, wherein the zeta-potential of the component (A) in the composition for chemical mechanical polishing is −10 mV or lower.

6. The composition for chemical mechanical polishing according to claim 1,
wherein the component (A) has a functional group represented by general formula (3) or general formula (4),
—NR¹R² (3)
—N⁺R¹R²R³M⁻ (4)
wherein in general formulas (3) and (4), R¹, R², and R³ each independently represent a hydrogen atom or a substituted or unsubstituted hydrocarbon group, and M⁻ represents an anion.

7. The composition for chemical mechanical polishing according to claim 6, wherein the zeta-potential of the component (A) in the composition for chemical mechanical polishing is +10 mV or higher.

8. The composition for chemical mechanical polishing according to claim 1, of which a pH is 1 or more and 6 or less.

9. The composition for chemical mechanical polishing according to claim 1, wherein a content of the component (A) is 0.005 mass % or more and 15 mass % or less with respect to a total mass of the composition for chemical mechanical polishing.

10. The composition for chemical mechanical polishing according to claim 1, further comprising at least one selected from the group consisting of water-soluble polymers and phosphoric acid esters.

11. A polishing method, comprising a step of polishing a semiconductor substrate using the composition for chemical mechanical polishing according to claim 1.

12. The polishing method according to claim 11, wherein the semiconductor substrate has a portion containing at least one of a polysilicon film and a silicon nitride film.
